(19) United States
(12) Patent Application Publication
(10) Pub. No.: US 2006/0140312 A1
(43) Pub. Date: Jun. 29, 2006

(54) Blind SNR estimation

(75) Inventor: Paul A. M. Bune, Kornwestheim (DE)

Correspondence Address: SUGHRUE MION, PLLC, 2100 PENNSYLVANIA AVENUE, N.W., SUITE 800, WASHINGTON, DC, 20037, US

(73) Assignee: ALCATEL

(21) Appl. No.: 11/298,750

(22) Filed: Dec. 12, 2005

(30) Foreign Application Priority Data
Dec. 28, 2004 (EP) 04293155.0

(51) Int. Cl. H03D 1/00

(52) U.S. Cl. 375/341

(57) ABSTRACT

A method for estimating the signal to noise ratio (=SNR) of a modulated communication signal including a data symbol component and a noise component is characterized in that an intermediate SNR value of the modulated communication signal is derived from a data assisted maximum-likelihood estimation, the assisting data not being known in advance but being reconstructed from samples of the modulated communication signal, and that an estimated SNR value is determined by a controlled non-linear conversion of the intermediate SNR value. This method allows an SNR estimation with high accuracy even for low numbers of processed samples.

### BACKGROUND OF THE INVENTION

The invention is based on a priority application EP 04293155.0 which is hereby incorporated by reference.

The invention relates to a method for estimating the signal to noise ratio (=SNR) (γ) of a modulated communication signal (rₙ) including a data symbol component (sₙ) and a noise component (nₙ).

An overview of SNR estimation techniques is given in D. R. Pauluzzi, N. C. Beaulieu, IEEE Trans. Comm. Vol. 48, Nr. 10, P. 1681-1691 (October 2000).

In order to provide optimal functioning of advanced mobile radio modules, accurate signal to noise ratio (=SNR) estimation of modulated communication signals is necessary. On the physical layer, SNR values are used in maximum-ratio combining and turbo-decoding. On higher layers, SNR values are used for call setup, macro diversity and handover control.

In environments with varying SNR, such as mobile radio networks, the determination of an SNR value must be rather quick.

The SNR value γ is defined as the ratio of signal power and noise power, i.e.

$$γ = \frac{signal power}{noise power} = \frac{{\vert signal amplitude \vert}^{2}}{noise power} .$$

SNR estimation can be done data-assisted (=DA) or Non-data assisted (NDA). The latter is often called a “blind” estimation.

In the case of data assisted SNR estimation, a set of samples (with one sample typically corresponding to one bit) is known in advance. After a transmission of the set of samples, the received data is compared with the original data by means of a data-assisted maximum likelihood estimation. The known set of samples can be a preamble or a training sequence.

If the transmitted set of samples is not known in advance, a blind estimation algorithm must be applied. Known algorithms of blind SNR estimation include
a) standard received data aided (=RDA) maximum likelihood SNR estimation (see e.g. D. Pauluzzi, N. Beaulieu, IEEE Trans. Comm., Vol 48, No 10, pp. 1681-1691, October 2000),
b) iterative SNR estimation (see e.g. B. Li et al., IEEE Commun. Lett. Vol 6, No 11, pp. 469-471, November 2002), and
c) Kurtosis SNR estimation (see e.g. R. Matzner, K. Letsch, Proc. IEEE-IMS Workshop on Information Theory and Statistics, Alexandria/Va., USA, p. 68ff, October 1994).

However, these known algorithms are rather inaccurate for low numbers of samples. Moreover, in particular the iterative SNR estimation is cumbersome and time consuming.

### SUMMARY OF THE INVENTION

It is the object of the present invention to provide a robust SNR estimation method for a modulated communication signal, wherein the method has a high accuracy even for low numbers of processed samples.

This object is achieved by a method as introduced in the beginning, characterized in that an intermediate SNR value (\hat{γ}_{RDA}) of the modulated communication signal is derived from a data assisted maximum-likelihood estimation, the assisting data not being known in advance but being reconstructed from samples of the modulated communication signal (rₙ), and that an estimated SNR value (\hat{γ}_{RDA-ER}) is determined by a controlled non-linear conversion of the intermediate SNR value (\hat{γ}_{RDA})

The inventive method estimates the SNR of the modulated communication signal by means of a conversion of the intermediate SNR value. The intermediate SNR value is obtained by a standard RDA maximum likelihood SNR estimation of the modulated communication signal. The intermediate SNR value \hat{γ}_{RDA} deviates from the true SNR value γ. In particular, for small values of the true SNR value γ, i.e. γ→0, \hat{γ}_{RDA} is much larger than γ. This deviation is compensated for by the controlled non-linear conversion of the intermediate SNR value.

The controlled non-linear conversion can be done by means of a conversion table based on an experimentally predetermined correlation between \hat{γ}_{RDA} and γ. It is preferred, however, to model the correlation between \hat{γ}_{RDA} and γ mathematically and to use the modelled correlation for conversion. For modelling, information about and/or suitable assumptions for the characteristics of the modulated communication signal are useful. In particular, the type of modulation should be known. It has been found that signals modulated by binary phase shift keying (=BPSK) can be handled very well by the inventive method. Moreover, the type of noise in the modulated communication signal can often be assumed to have a Gaussian distribution.

With the aid of the highly accurate and robust estimated SNR values obtained over a broad SNR range, as determined by means of the invention, it is possible to improve receiver performance, which in turn allows for distressing of margins e.g. in network planning, in particular lower UL/DL transmission power requirements and larger distances between base stations, nodes B and the like.

A highly preferred variant of the inventive method is characterized in that the controlled non-linear conversion is performed by a correction function Ψ⁻¹, with \hat{γ}_{RDA-ER}=Ψ⁻¹(\hat{γ}_{RDA}), wherein the correction function Ψ⁻¹ is the inverse function of an estimated deviation function Ψ, with the estimated deviation function Ψ approximating a true deviation function Ψₜᵣᵤₑ correlating the deviation of \hat{γ}_{RDA} from γ, i.e. \hat{γ}_{RDA}=Ψₜᵣᵤₑ(γ) and Ψ(γ)≈Ψₜᵣᵤₑ(γ). Typically, the estimated deviation function is determined by a mathematic model. Its inverse function, i.e. the correction function, can be obtained by mirroring the estimated deviation function at the bisecting line of the first quadrant in the coordinate system. If the estimated deviation function is simple enough, its inverse function can also be calculated analytically. The estimated deviation function Ψ(γ) can be calculated by setting it equal to the intermediate SNR signal, which in turn is the ratio of the estimated signal power and the estimated noise power of the modulated communication signal. The estimated signal power and estimated noise power, then, must be expressed as a function of γ, with the latter requiring suitable assumptions, such as e.g. an infinite number of samples to be processed.

In a preferred further development of this method, Ψ is chosen such that Ψ(γ)=Ψₜᵣᵤₑ(γ) for large numbers of N, i.e. N→∞, with N being the number of samples of the modulated communication signal (rₙ) being processed. The estimated deviation function found in this way is then applied to data with a finite number of samples, too. In many cases, in particular with a BPSK modulation and Gaussian noise distribution, Ψₜᵣᵤₑ(γ) can be determined accurately for N→∞. The latter assumption is justified in most real situations, when sufficiently large numbers of samples are available. In particular, a number of 100 samples or more is sufficient.

In a further preferred development of said variant of the inventive method,

$$Ψ ( γ ) = \frac{1}{\frac{γ + 1}{{( \sqrt{γ} erf ( \sqrt{\frac{γ}{2}} ) + \sqrt{\frac{2}{π} {ⅇ}^{- \frac{γ}{2}}} )}^{2}} - 1} .$$

This choice of Ψ(γ) gives highly accurate results in case of a BPSK modulation of the modulated communication signal.

In an advantageous development of the variant, Ψ⁻¹ is applied by means of an approximation table. An approximation table provides very quick access to values of the correction function, which are listed in the table. Alternatively, online numerical or analytical calculation of values of the correction function is also possible, but more time consuming.

Further preferred is a development of said variant wherein

$$Ψ ( γ ) = {Ψ}_{HA} ( γ ) = \sqrt{{γ}^{2} + {( \frac{2}{π - 2} )}^{2}} .$$

This hyperbolic function is a good approximation of Ψₜᵣᵤₑ(γ) in case of BPSK modulation. Its inverse can be calculated straightforwardly as

$${Ψ}_{HA}^{- 1} ( γ ) = \sqrt{{{γ}^{2} ( \frac{2}{π - 2} )}^{2}} for γ \geq \frac{2}{π - 2} , and$$

$${Ψ}_{HA}^{- 1} ( γ ) = 0 for γ = \leq \frac{2}{π - 2} .$$

Thus, the correction function is available analytically, which simplifies and accelerates the determination of the estimated SNR value \hat{γ}_{RDA-ER}.

In another variant of the inventive method, the number N of samples of the modulated communication signal (rₙ) being processed is equal or less than 500, preferably equal or less than 100. In these cases, the inventive method already provides estimated SNR values of high accuracy, whereas known methods show worse accuracy. For higher values of N, such as an N of 1000 or larger, it is worth mentioning that the inventive method provides equally accurate estimated SNR values as known methods, but typically with less effort.

Also in the scope of the invention is a computer program for estimating the signal to noise ratio (γ) of a modulated communication signal (rₙ) according to the inventive method. The computer program may be saved on a storage medium, in particular a hard disk or a portable storage medium such as a compact disc.

The invention also comprises a receiver system for estimating the signal to noise ratio (γ) of a modulated communication signal (rₙ) according to the inventive method. The receiver system comprises a receiver unit. The receiver unit can receive transmitted signals, with the transmission carried out by radio or an optical fibre line, e.g.. The inventive method can be performed directly with the received transmitted signals, i.e. at the receiver unit. Alternatively, the inventive method can be applied after a channel decoding, such as turbo decoding, of the received transmitted signals. In the latter case, the method is performed with “soft” signals.

Finally, the invention is also realized in an apparatus, in particular a base station or a mobile station, comprising an inventive computer program and/or an inventive receiver system as described above. A typical mobile station is a mobile phone. An inventive apparatus can be part of a 3G or B3G network, in particular a UMTS network or a WLAN network.

Further advantages can be extracted from the description and the enclosed drawing. The features mentioned above and below can be used in accordance with the invention either individually or collectively in any combination. The embodiments mentioned are not to be understood as exhaustive enumeration but rather have exemplary character for the description of the invention.

### BRIEF DESCRIPTION OF THE DRAWINGS

The invention is shown in the drawing.

FIG. 1 shows a binary transmission system with a noisy channel for use with the inventive method;

FIG. 2 shows plots of an estimated deviation function Ψ(γ) for a BPSK real channel and a hyperbolic function Ψ_{HA}(γ) which approximates the former function, as well as their inverse functions in accordance with the invention;

FIG. 3a shows a diagram plotting normalized mean square errors of estimated SNR values with respect to the true SNR values as a function of the true SNR value, for standard RDA maximum likelihood SNR estimation (state of the art), inventive RDA-ER and inventive RDA-ERHA, with 100 samples processed per SNR estimation;

FIG. 3b shows a diagram corresponding to FIG. 3a, with 1000 samples per SNR estimation;

FIG. 4a shows a diagram plotting normalized mean square errors of estimated SNR values with respect to the true SNR values as a function of the true SNR value, for standard RDA maximum-likelihood SNR estimation (state of the art), inventive RDA-ER, Iterative method (state of the art) and Kurtosis method (state of the art) with 100 samples processed per SNR estimation;

FIG. 4b show a diagram corresponding to FIG. 4a, with 1000 samples processed per SNR estimation.

### DETAILED DESCRIPTION OF THE DRAWINGS

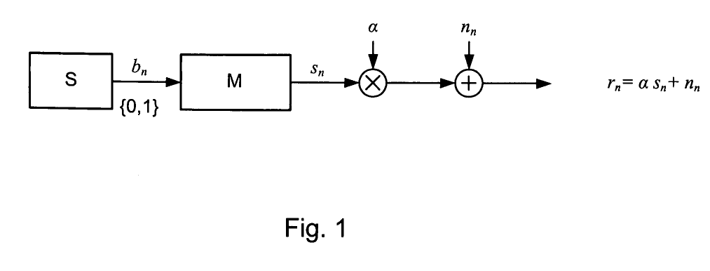

The invention deals with the estimation of SNR values in a transmission system, such as a radio telephone network. A transmission system for use with the invention is shown schematically in FIG. 1. At a source S, binary data is generated. The binary data may contain information of a telephone call, for example. The binary data consists of a number of bits bₙ, with n: the index number of the bits, running from 0 to N−1, with N: the total number of bits of the binary data. Each bit may have a value of 0 or 1. In order to transport the binary data, it is modulated in a modulator M. A typical modulation is the binary phase shift keying (BPSK) modulation, resulting in values of a data symbol component sₙ of +1 or −1. At the physical transmission of the data symbol component sₙ, typically applying a carrier frequency, sₙ is amplified by a factor α. Also, noise nₙ is superposed by the channel to the amplified data symbol component α·sₙ. The amplification factor α and the noise level are unknown initially. Thus in total, a modulated communication signal rₙ=α·sₙ+nₙ is generated and ready for detection at a receiver system. The receiver system may be part ofa mobile phone, for example. During the physical transport, other data symbol components may be transmitted at the same time at other frequency ranges and/or at other (spreading) code ranges. These other data symbol components can be neglected in this context; they may affect the noise component nₙ, though.

In the following, a BPSK modulation is assumed as well as a real channel, with a noise probability density function (=PDF) of Gaussian type

$$p ( {n}_{n} ) = \frac{1}{σ \sqrt{2 π}} {ⅇ}^{- \frac{{n}_{n}^{2}}{2 {σ}^{2}}} ,$$

with σ: standard deviation or noise amplitude. However, other signal characteristics are possible in accordance with the inverntion.

When making a data-aided (DA) maximum-likelihood SNR estimation, an estimated amplitude \hat{α} with known “pilots” sₙ, i.e. a set of N known data symbol component values, is calculated as

$$\hat{α} = E \{ \frac{{r}_{n}}{{s}_{n}} \} = \frac{1}{N} {\sum }_{n = 0}^{N - 1} \frac{{r}_{n}}{{s}_{n}} = \frac{1}{N} {\sum }_{n = 0}^{N - 1} {r}_{n} {s}_{n} ,$$

with sₙ={+1, −1}. Note that a hat ˆ above a value indicates an estimated value, and E is the estimation operation determining the mean value of its input values. The estimated noise power \hat{σ}² (second moment) is calculated as

$$\begin{matrix}{\hat{σ}}^{2} = E \{ {( {r}_{n} - \hat{α} {s}_{n} )}^{2} \} \\ = E \{ {r}_{n}^{2} \} - {\hat{α}}^{2} E \{ {s}_{n}^{2} \} \\ = \frac{1}{N - v} {\sum }_{n = 0}^{N - 1} {( {r}_{n} - \hat{α} {s}_{n} )}^{2} ,\end{matrix}$$

with ν being a constant to be chosen according to literature (D. R. Pauluzzi, N. C. Beaulieu, I.c.) as follows: Maximum likelihood for σ² estimation: v=0; Bias elimination for σ² estimation: v=1; Minimum MSE for σ² estimation: v=−1; Bias elimination for γ estimation: v=3; Minimum MSE for γ estimation: v=5. The data-aided SNR estimation then results in

$$\begin{matrix}{\hat{γ}}_{DA} = \frac{{\hat{α}}^{2}}{{\hat{σ}}^{2}} \\ = \frac{{( \frac{1}{N} {\sum }_{n = 0}^{N - 1} {r}_{n} {s}_{n} )}^{2}}{\frac{1}{N - v} {\sum }_{n = 0}^{N - 1} {r}_{n}^{2} - \frac{1}{N ( N - v )} {( {\sum }_{n = 0}^{N - 1} {r}_{n} {s}_{n} )}^{2}} \\ = \frac{( N - v )}{N} {\hat{γ}}_{v = 0} .\end{matrix}$$

In case of a “blind”, i.e. received-data-aided (RDA) maximum likelihood SNR estimation, the “pilots” are estimated based on receiver decisions, identical to the first absolute moment. The estimated amplification factor \hat{α} is calculated as

$$\hat{α} = E \{ {r}_{n} {\hat{s}}_{n} \} = E \{ {r}_{n} signum ( {r}_{n} ) \} = E \{ \vert {r}_{n} \vert \} = \frac{1}{N} {\sum }_{n = 0}^{N - 1} \vert {r}_{n} \vert .$$

Noise power is estimated correspondingly (compare DA above). Accordingly, an SNR value is estimated, with

$${\hat{γ}}_{BPSK 1 , RDA} = \frac{{( \frac{1}{N} {\sum }_{n = 0}^{N - 1} \vert {r}_{n} \vert )}^{2}}{\frac{1}{N - v} {\sum }_{n = 0}^{N - 1} {r}_{n}^{2} - \frac{1}{N ( N - v )} {( {\sum }_{n = 0}^{N - 1} \vert {r}_{n} \vert )}^{2}} .$$

This value \hat{γ}_{BPSK1,RDA} is the result of the standard RDA maximum likelihood SNR estimation, as known from literature.

However, by using estimated data symbol component values ŝₙ instead of the true data symbol component values sₙ, error is introduced. For sufficiently large SNR values γ, \hat{γ}_{BPSK1,RDA} approximates γ very well, but for small values of γ, the estimated values \hat{γ}_{BPSK1,RDA} are too large.

According to the invention, the \hat{γ}_{BPSK1,RDA} value is set equal to an estimated deviation function Ψ(γ). For this purpose, the terms of \hat{γ}_{BPSK1,RDA} are expressed as functions of the true SNR value γ, requiring some approximations and assumptions:

$$\hat{α} = E \{ \vert {r}_{n} \vert \} = E \{ α + \vert {n}_{n} \vert \} = \frac{1}{σ} \sqrt{\frac{2}{π}} {\int }_{0}^{∞} ρ {ⅇ}^{\frac{{ρ}^{2} + {α}^{2}}{2 {σ}^{2}}} cos h ( \frac{α}{{σ}^{2}} ρ ) ⅆ ρ = αerf ( \sqrt{\frac{γ}{2}} ) + σ \sqrt{\frac{2}{π}} {ⅇ}^{\frac{γ}{2}} {\hat{α}}^{2} + {\hat{σ}}^{2} = E \{ {r}_{n}^{2} \} = \frac{1}{σ \sqrt{2 π}} {\int }_{0}^{∞} \sqrt{υ} {ⅇ}^{\frac{υ + {α}^{2}}{2 {σ}^{2}}} cos h ( \frac{α}{{σ}^{2}} \sqrt{υ} ) ⅆ υ = {α}^{2} + {σ}^{2} \\ {\hat{γ}}_{BPSK 1 , RDA} = \frac{{\hat{α}}^{2}}{{\hat{σ}}^{2}} = \frac{{( E \{ \vert {r}_{n} \vert \} )}^{2}}{E \{ {r}_{n}^{2} \} - {( E \{ \vert {r}_{n} \vert \} )}^{2}} = \frac{1}{\frac{E \{ {r}_{n}^{2} \}}{{( E \{ \vert {r}_{n} \vert \} )}^{2}} - 1} = \frac{1}{\frac{γ + 1}{{( \sqrt{γ} erf ( \sqrt{\frac{γ}{2}} ) + \sqrt{\frac{2}{π}} {ⅇ}^{\frac{γ}{2}} )}^{2}} - 1} {=}^{△} Ψ ( γ )$$

In particular, the one-dimensional Gaussian type noise PDF as defined in the beginning has been introduced in this calculation, and it is based on the BPSK modulation (indicated by the index BPSK1, where the “1” represents the one-dimensionality of the real channel and its noise).

The result \hat{γ}_{BPSK1,RDA} of the standard RDA maximum likelihood estimation is used as a starting point for the actual calculation of an estimated SNR value \hat{γ}_{BPSK1,RDA-ER} in accordance with the invention. For this reason, the \hat{γ}_{BPSK1,RDA} is called an intermediate SNR value. The “ER” index of \hat{γ}_{BPSK1,RDA-ER} indicates an extended range, i.e. an improved range of application with the invention. For calculating \hat{γ}_{BPSK1,RDA-ER}, the inverse function Ψ⁻¹ of the estimated deviation function Ψ(γ) is determined, and the intermediate SNR value \hat{γ}_{BPSK1,RDA} is assigned to Ψ⁻¹, with \hat{γ}_{BPSK1,RDA-ER}=Ψ⁻¹(\hat{γ}_{BPSK1,RDA}). Note that

$${Ψ}^{- 1} ( x ) = 0 for x \leq \frac{2}{π - 2} .$$

The correlation of \hat{γ}_{BPSK1,RDA}=Ψ(γ) is, due to the assumptions and simplifications necessary to express \hat{γ}_{BPSK1,RDA} in terms of γ, only an approximation of the true and exact correlation \hat{γ}_{BPSK1,RDA}=Ψₜᵣᵤₑ(γ). The better Ψ(γ) approximates Ψₜᵣᵤₑ(γ), the more accurate is the estimated SNR value \hat{γ}_{BPSK1,RDA-ER} in accordance with the invention.

In the above-calculated case of BPSK over a real channel, the estimated deviation function Ψ cannot be inverted to a closed form inverse function, so numerical calculation is necessary. However, for simplification, the estimated deviation function Ψ can be approximated by a hyperbolic function Ψ_{HA} which is easy to invert:

$$\begin{matrix}Ψ ( x ) \approx {Ψ}_{HA} ( x ) = \sqrt{{x}^{2} + {( \frac{2}{π - 2} )}^{2}} & \\ {Ψ}^{- 1} ( x ) \approx {Ψ}_{HA}^{- 1} ( x ) = \sqrt{{x}^{2} - {( \frac{2}{π - 2} )}^{2}} & for x \geq \frac{2}{π - 2} \\ {Ψ}^{- 1} ( x ) = {Ψ}_{HA}^{- 1} ( x ) = 0 & for x \leq \frac{2}{π - 2} .\end{matrix}$$

Then the inventive estimated SNR value can be calculated as
\hat{γ}_{BPSK1,RDA-ERHA}=Ψ_{HA}⁻¹(\hat{γ}_{BPSK1,RDA}).

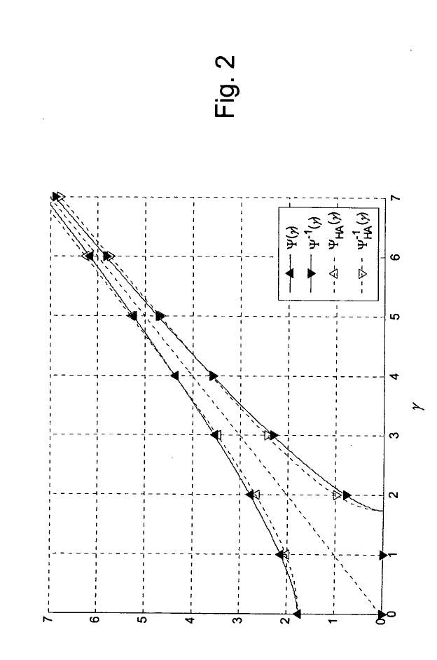

In FIG. 2, the function

$$Ψ ( γ ) = \frac{1}{\frac{γ + 1}{{( \sqrt{γ} erf ( \sqrt{\frac{γ}{2}} ) + \sqrt{\frac{2}{π}} {ⅇ}^{- \frac{γ}{2}} )}^{2}} - 1}$$

as well as the function

$${Ψ}_{HA} ( γ ) = \sqrt{{γ}^{2} + {( \frac{2}{π - 2} )}^{2}}$$

which approximates the former function are plotted for comparison. The differences are about 0.2 absolutely and about 10% relatively at maximum. Their inverse functions, which are available by mirroring the plots at the bisecting line of the first quadrant (dashed line without symbols), are also indicated in FIG. 2.

In order to quantify the accuracy of the inventive method for estimating SNR values of modulated communication signals, different SNR estimation methods of the state of the art and according to the invention have been tested.

A number Nₜ of tests is performed with every method. Each test is done with a disjunctive set of N symbols (or bits, samples). The corresponding modulated communication signals rₙ of each set, with n running from 0 to N−1, have a known true SNR value γ. In each test, an estimated SNR value \hat{γ}ₘ of the tested set is determined by means of the currently tested method, with m: test index (or index of tested sets) running from 0 to Nₜ−1. The distribution of the estimated SNR values \hat{γ}ₘ as compared with the true SNR value γ is analysed by calculating a normalized mean square error (NMSE) of \hat{γ}ₘ:

$$NMSE \{ {\hat{γ}}_{m} \} = \frac{MSE \{ {\hat{γ}}_{m} \}}{{γ}^{2}} = \frac{E \{ {( {\hat{γ}}_{m} - γ )}^{2} \}}{{γ}^{2}} = \frac{1}{{N}_{t} {γ}^{2}} {\sum }_{m = 0}^{{N}_{t} - 1} {( {\hat{γ}}_{m} - γ )}^{2} .$$

The NMSE values are, for each method, a function of the true SNR value γ and a function of the number of samples N of each set.

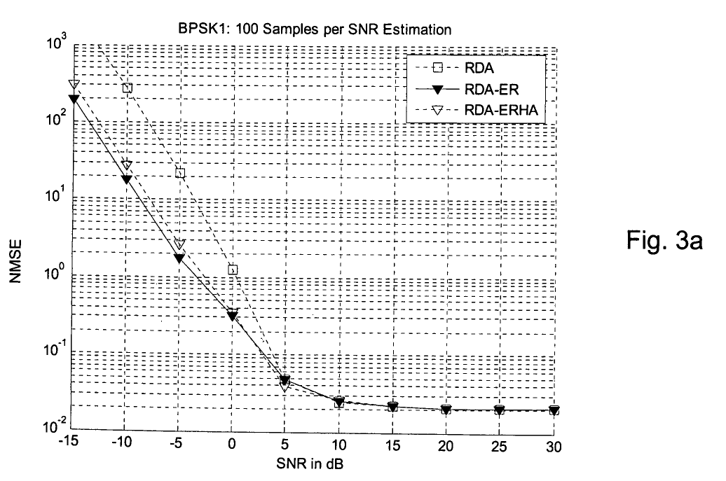

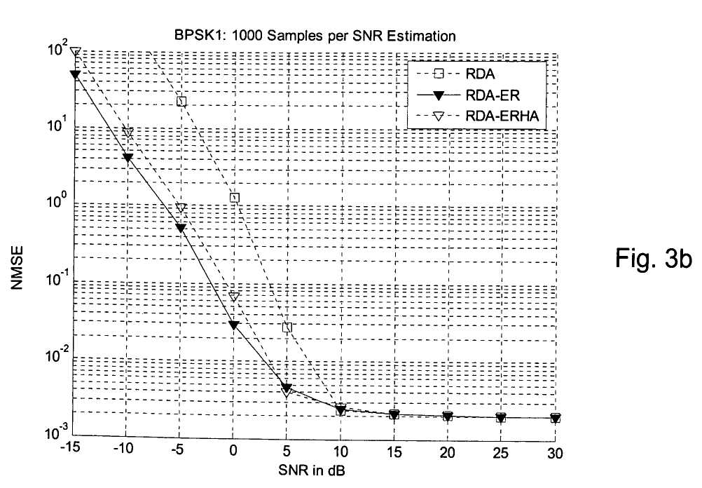

Test results are plotted in FIG. 3a. The abscissa shows the true SNR γ in dB, and the ordinate shows on a logarithmic scale the NMSE values of estimated SNR values for three different methods, i.e. standard RDA maximum likelihood estimation of the state of the art, inventive RDA-ER maximum likelihood estimation with the estimated deviation function Ψ as in FIG. 2, and inventive RDA-ERHA maximum likelihood estimation with the estimated deviation function Ψ_{HA} as in FIG. 2. For the diagram, all in all 10⁶ SNR estimations (tests) have been calculated, with N=100 samples per SNR estimation.

For low SNR values (0 dB and less), the NMSE values of the inventive RDA-ER and RDA-ERHA methods are much lower than the NMSE values of the state of the art standard RDA method. In other words, the inventive methods are more accurate in this range. In particular, at −10 dB and −5 dB, the inventive methods are about 10 times more accurate than standard RDA. In said range, RDA-ER NMSE values are about half of the RDA-ERHA NMSE values. For higher SNR values (5 dB and above), all three methods are roughly equally accurate.

For FIG. 3b, the same tests as for FIG. 3a have been performed, but with N=1000 samples per SNR estimation. The relative difference in accuracy between state of the art RDA on the one hand and inventive RDA-ER and RDA-ERHA is even higher, showing the improvement by the inventive method.

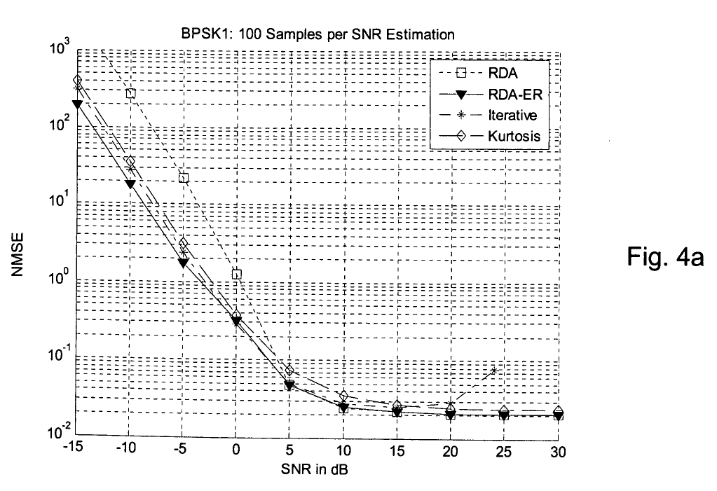

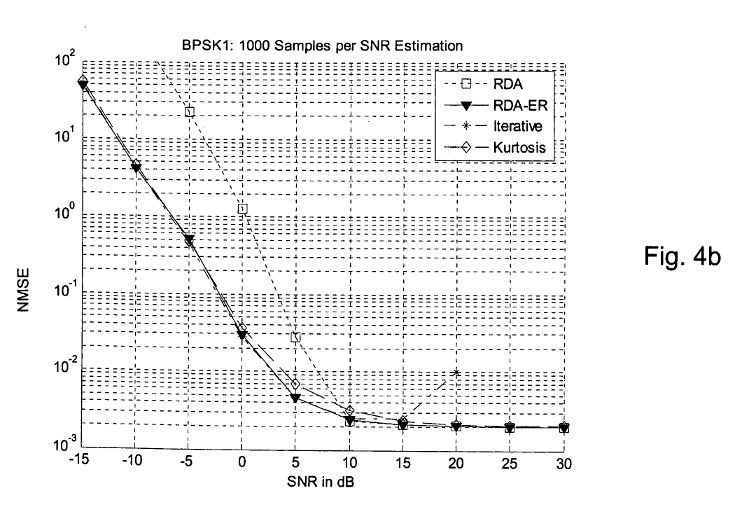

For FIG. 4a, the same tests as for FIG. 3a have been performed, with N=100 samples per SNR estimation again. The NMSE values of estimated SNR values are plotted for the standard RDA maximum likelihood estimation method of the state of the art, the inventive RDA-ER maximum likelihood estimation method, the Iterative method of the state of the art, and the Kurtosis method of the state of the art. The inventive RDA-ER method has the lowest NMSE values, indicating the highest accuracy, over a very broad SNR range. In the range of 0 dB to 5 dB, the Iterative method is roughly equal to the inventive RDA-ER method.

For FIG. 4b, the same tests as for FIG. 4a have been performed, but with N=1000 samples per SNR estimation. For low SNR values (0 dB and less), the inventive RDA-ER method, the Iterative method and the Kurtosis method are equally accurate. For SNR values of 10 dB and above, the inventive RDA-ER method clearly outperforms the Iterative method. Moreover, the inventive RDA-ER method outperforms the Kurtosis method between 0 dB and 15 dB.

In summary, the inventive SNR estimation method has been tested for a BPSK channel over a real AWGN channel. It outperforms or is at least equal to known blind SNR estimation algorithms. The inventive method can easily be used with other signal modulations over real or complex channels. The inventive method requires only limited effort (a little more than the well-known maximum likelihood data assisted estimation); in particular, it does neither need iteration nor decoding/re-encoding of protected data. Finally, to avoid the storage and the handling of the optimal interpolation curve Ψ⁻¹, a hyperbolical approximation is available which allows instantaneous computation with only minor performance degradation.

1. Method for estimating the signal to noise ratio (=SNR) (γ) of a modulated communication signal (rₙ) including a data symbol component (sₙ) and a noise component (nₙ), wherein
an intermediate SNR value (\hat{γ}_{RDA}) of the modulated communication signal is derived from a data assisted maximum-likelihood estimation, the assisting data not being known in advance but being reconstructed from samples of the modulated communication signal (rₙ),
and an estimated SNR value (\hat{γ}_{RDA-ER}) is determined by a controlled non-linear conversion of the intermediate SNR value (\hat{γ}_{RDA}).

2. Method according to claim 1, characterized in that the controlled non-linear conversion is performed by a correction function Ψ⁻¹, with \hat{γ}_{RDA-ER}=Ψ⁻¹(\hat{γ}_{RDA}), wherein the correction function Ψ⁻¹ is the inverse function of an estimated deviation function Ψ, with the estimated deviation function Ψ approximating a true deviation function Ψₜᵣᵤₑ correlating the deviation of \hat{γ}_{RDA} from γ, i.e. \hat{γ}_{RDA}=Ψₜᵣᵤₑ(γ) and Ψ(γ)≈Ψₜᵣᵤₑ(γ).

3. Method according to claim 2, characterized in that Ψ is chosen such that Ψ(γ)=Ψₜᵣᵤₑ(γ) for large numbers of N, i.e. N→∞, with N being the number of samples of the modulated communication signal (rₙ) being processed.

4. Method according to claim 2, characterized in that
$$Ψ ( γ ) = \frac{1}{\frac{γ + 1}{{( \sqrt{γ} erf ( \sqrt{\frac{γ}{2}} ) + \sqrt{\frac{2}{π}} {ⅇ}^{- \frac{γ}{2}} )}^{2}} - 1} .$$

5. Method according to claim 2, characterized in that Ψ⁻¹ is applied by means of an approximation table.

6. Method according to claim 2, characterized in that
$$Ψ ( γ ) = {Ψ}_{HA} ( γ ) = \sqrt{{γ}^{2} + {( \frac{2}{π - 2} )}^{2}} .$$

7. Method according to claim 1, characterized in that the number N of samples of the modulated communication signal (rₙ) being processed is equal or less than 500, preferably equal or less than 100.

8. Computer program for estimating the signal to noise ratio (γ) of a modulated communication signal (rₙ) to noise ratio (=SNR) (γ) of a modulated communication signal (rₙ) including a data symbol component (sₙ) and a noise component (nₙ), wherein an intermediate SNR value (\hat{γ}_{RDA}) of the modulated communication signal is derived from a data assisted maximum-likelihood estimation, the assisting data not being known in advance but being reconstructed from samples of the modulated communication signal (rₙ), and that an estimated SNR value (\hat{γ}_{RDA-ER}) is determined by a controlled non-linear conversion of the intermediate SNR value (\hat{γ}_{RDA}).

9. Receiver system for estimating the signal to noise ratio (γ) of a modulated communication signal (rₙ) to noise ratio (=SNR) (γ) of a modulated communication signal (rₙ) including a data symbol component (sₙ) and a noise component (nₙ), wherein an intermediate SNR value (\hat{γ}_{RDA}) of the modulated communication signal is derived from a data assisted maximum-likelihood estimation, the assisting data not being known in advance but being reconstructed from samples of the modulated communication signal (rₙ), and that an estimated SNR value (\hat{γ}_{RDA-ER}) is determined by a controlled non-linear conversion of the intermediate SNR value (\hat{γ}_{RDA}).

10. Apparatus, in particular a base station or a mobile station, comprising a computer program for estimating the signal to noise ratio (γ) of a modulated communication signal (rₙ) to noise ratio (=SNR) (γ) of a modulated communication signal (rₙ) including a data symbol component (sₙ) and a noise component (nₙ), wherein an intermediate SNR value (\hat{γ}_{RDA}) of the modulated communication signal is derived from a data assisted maximum-likelihood estimation, the assisting data not being known in advance but being reconstructed from samples of the modulated communication signal (rₙ), and that an estimated SNR value (\hat{γ}_{RDA-ER}) is determined by a controlled non-linear conversion of the intermediate SNR value (\hat{γ}_{RDA}).

11. Apparatus, in particular a base station or a mobile station, comprising a receiver system for estimating the signal to noise ratio (γ) of a modulated communication signal (rₙ) to noise ratio (=SNR) (γ) of a modulated communication signal (rₙ) including a data symbol component (sₙ) and a noise component (nₙ), wherein an intermediate SNR value (\hat{γ}_{RDA}) of the modulated communication signal is derived from a data assisted maximum-likelihood estimation, the assisting data not being known in advance but being reconstructed from samples of the modulated communication signal (rₙ), and that an estimated SNR value (\hat{γ}_{RDA-ER}) is determined by a controlled non-linear conversion of the intermediate SNR value (\hat{γ}_{RDA}).
